(19) United States
(12) Patent Application Publication
(10) Pub. No.: US 2007/0059874 A1
(43) Pub. Date: Mar. 15, 2007

(54) Dual Metal Gate and Method of Manufacture

(75) Inventors: Naim Moumen, Walden, NY (US); Husam Alshareef, Austin, TX (US); Joel Barnett, Austin, TX (US); Muhammad Mustafa Hussain, Austin, TX (US); Hongfa Luan, Dresden (DE); Seung-Chul Song, Austin, TX (US); Raj Jammy, Austin, TX (US)

Correspondence Address: FULBRIGHT & JAWORSKI L.L.P., 600 CONGRESS AVE., SUITE 2400, AUSTIN, TX, 78701, US

(73) Assignee: SEMATECH, Inc.

(21) Appl. No.: 11/456,054

(22) Filed: Jul. 6, 2006

Related U.S. Application Data
(60) Provisional application No. 60/696,848, filed on Jul. 6, 2005.

(51) Int. Cl. H01L 21/8238

(52) U.S. Cl. 438/199; 438/296; 257/E21.632

(57) ABSTRACT

Methods for fabricating two metal gate stacks for complementary metal oxide semiconductor (CMOS) devices are provided. A common layer, such as a metal layer, a metal alloy layer, or a metal nitride layer may be deposited on to a gate dielectric. A first mask layer may be deposited and patterned over an active region, exposing a portion of the common layer. A first ion may be deposited in the common layer forming a first mask layer. Similarly, a second mask layer may be deposited and patterned over the other active region and the first metal layer, and another portion of the common layer is exposed. A second ion may be deposited in the common layer, forming a second mask layer.

This application claims priority to, and incorporates by reference, U.S. Provisional Patent Application Ser. No. 60/696,848, filed Jul. 6, 2005.

### BACKGROUND OF THE INVENTION

1. Field of the Invention

The present invention relates generally to semiconductor fabrication, and more particularly to a method for fabricating dual metal gate devices.

2. Description of Related Art

Semiconductor devices are continuously improved to enhance device performance. For example, smaller device sizes allow for the ability to construct smaller gate structures for complementary metal oxide semiconductor (CMOS) transistors such that more transistors are fitted on the same surface area, improving the switching speed of the transistor among other benefits. With CMOS technology scaling to approximately 45 nm or less, the conventional poly-silicon dioxide gate stack is reaching its scaling limitation. Issues such as power dissipation and tunneling become more prevalent when the vertical dimension is reduced, e.g., decreasing the thickness of the SiO₂ gate dielectrics.

One alternative to the poly-silicon gate electrode is a metal gate, particularly a dual metal gate stack. Dual metal gate stacks generally require two separate metals, one metal over the NMOS active area and the other over the PMOS active region. These two metals may be selected based on their workfunction and ease of integration during wet and/or dry etch processes.

A conventional method for integrating dual metal gate CMOS is shown in FIG. 1. In step 100, after the deposition of first metal layer 4 on gate dielectric layer 2 which spans across an NMOS active area and a PMOS active area of substrate 10, hardmask layer 12 is deposited followed by photoresist layer deposition for creating photoresist layer 14. First metal layer 4 of FIG. 1 may be an NMOS metal layer including a metal such as TaSiN, TiN, TaN, or the like. Alternatively, first metal layer 4 of FIG. 1 may a PMOS metal layer including a metal such as Ru, Mo, W, P, or the like. Next, photoresist layer 14 may be patterned, using techniques know in the art, to define the boundary of the hardmask layer for subsequent steps.

In step 102, hardmask layer 12 is etched to align with an active region (e.g., NMOS active region) and a gate region. Also in step 102, after the hardmask etching is complete, photoresist layer 14 is removed.

Next, the first metal layer 4 is etched using an etching process, such as a wet-etch process, as shown in step 104. After first metal layer 4 is etched, hardmask layer 12 is etched, as shown in step 106. It is noted that steps 100 through 106 forms the first metal layer in the dual metal gate stack.

In step 108, second metal layer 6 is deposited over first metal layer 4 and the other active region, e.g., the PMOS active region. After the second metal layer deposition, poly silicon layer 8 is deposited. In step 110, multiple etching processes are completed resulting in a gate stack over the NMOS active region and the PMOS active region.

However, the above conventional dual metal gate integration process can provide many challenges. In steps 106 and 108, the underlying gate dielectric layer may be damaged during the etching process of first metal layer 4 and/or the etching process of hardmask layer 12. Further, normal metal etch chemistry such as SPM, SCl, or H₂O₂ tends to also etch the photoresist layer at a high etch rate, particularly if first metal layer 4 is an NMOS metal layer. The etching of the photoresist layer makes it difficult to preserve the metal layer on the active region, e.g., an NMOS metal on an NMOS region or a PMOS metal on a PMOS region.

In step 110, complications may arise from the simultaneous patterning of two gate stacks that are different in thickness and composition. For example, the NMOS gate stack includes two metal layers and a poly layer as compared to the PMOS gate stack which only has one metal layer and a poly layer. Further, subsequent fabrication processes, such as an anneal process may cause the two metal layers in the NMOS gate stack to intermix. Any of the above complications may contribute to device failure, reduction in yield, and higher production cost.

Any shortcoming mentioned above is not intended to be exhaustive, but rather is among many that tends to impair the effectiveness of previously known techniques for fabricating a dual metal gate stack; however, shortcomings mentioned here are sufficient to demonstrate that the methodologies appearing in the art have not been satisfactory and that a significant need exists for the techniques described and claimed in this disclosure.

### SUMMARY OF THE INVENTION

By replacing the poly gate electrodes with a dual work function metal gate electrode, issues such as polysilicon depletion may be reduced or substantially eliminated and inversion capacitance may be increased as compared to standard polysilicon/SiO₂ gate. Particularly, the present disclosure describes an integration method that minimizes or substantially eliminates the impact on an underlying gate dielectric layer upon removing or etching of a first and/or second metal layer.

In one respect, the disclosure involves a method for fabricating metal gate stacks. The method may include providing a substrate comprising two active areas (e.g., an NMOS active region and a PMOS active region) and a gate dielectric layer. Next, a common metal layer may be deposited over the gate dielectric. A first mask layer may be deposited onto the common metal layer and can be patterned expose a first portion of the common metal layer, while protecting one of the active regions of the substrate. An ion may be deposited into the exposed first portion of the common metal layer to form a first metal layer.

Similarly, a second mask layer may be deposited onto the substrate. In one embodiment the second mask layer is deposited onto the first metal layer and common metal layer and may subsequently patterned to expose a second portion of the common metal layer. The second mask layer may protect the first metal layer. Next, another ion may be deposited into the exposed second portion of the common metal layer to form a second metal layer.

In other embodiments, after the first and second metal layers are formed, a cap, such as an amorphous silicon cap may deposited over the entire device area. A photoresist layer may be deposited directly on the cap and may be patterned to form an area over the first gate region and second gate region. An etching process, etching the cap may be performed. After etching the cap, the first and second metal layers may be etched simultaneously, forming the first and second metal gate stack.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The figures are examples only. They do not limit the scope of the invention.

FIG. 1 shows a prior art flowchart of a method for a semiconductor fabrication process.

FIG. 2 shows a flowchart of a method for integrating dual metal gate stacks, in accordance with embodiments of this disclosure.

FIG. 3 shows a flowchart of a method for integrating dual metal gate stacks, in accordance with embodiments of this disclosure.

FIG. 4 shows a cross section of a FINFET device, in accordance with embodiments of this disclosure.

FIG. 5 show results of from implanting ions into a high-k dielectric layer and a metal gate layer, in accordance with embodiments of this disclosure.

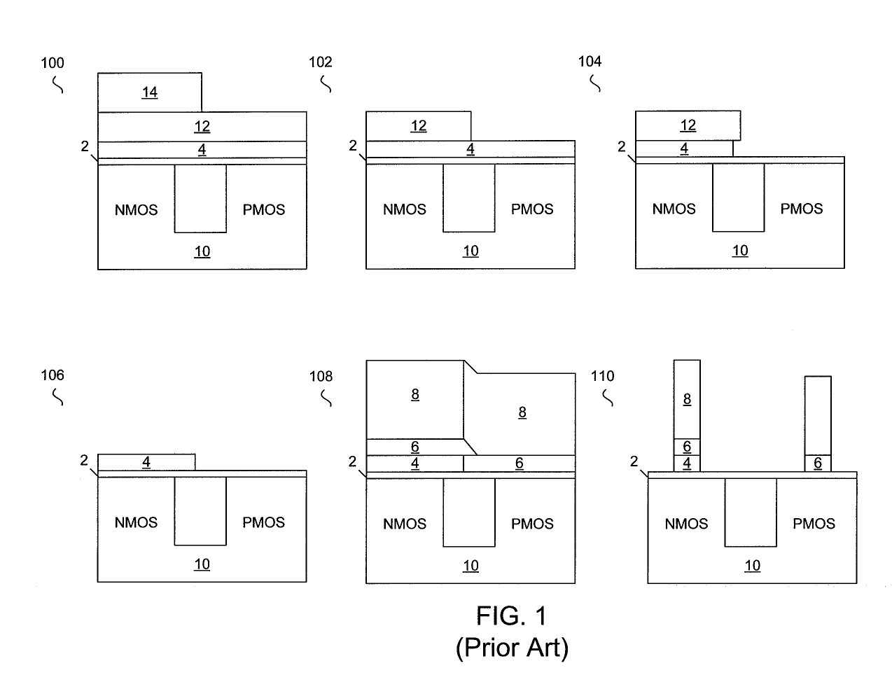

### DESCRIPTION OF ILLUSTRATIVE EMBODIMENTS

The disclosure and the various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to those skilled in the art from this disclosure.

The disclosure provides methods for fabricating dual metal gate structures on devices such as a CMOS device or non-planar devices (e.g., FINFETs) while minimizing or substantially eliminating damages to an underlying high-k gate dielectric layer. Particularly, in some embodiments, the present disclosure provides a common metal element layer and an ion implantation process for depositing metal layers onto a substrate. The common layer may be a matrix film may include a similar common metal element that may be used to form the two metal layers and subsequently the dual metal gates on a substrate.

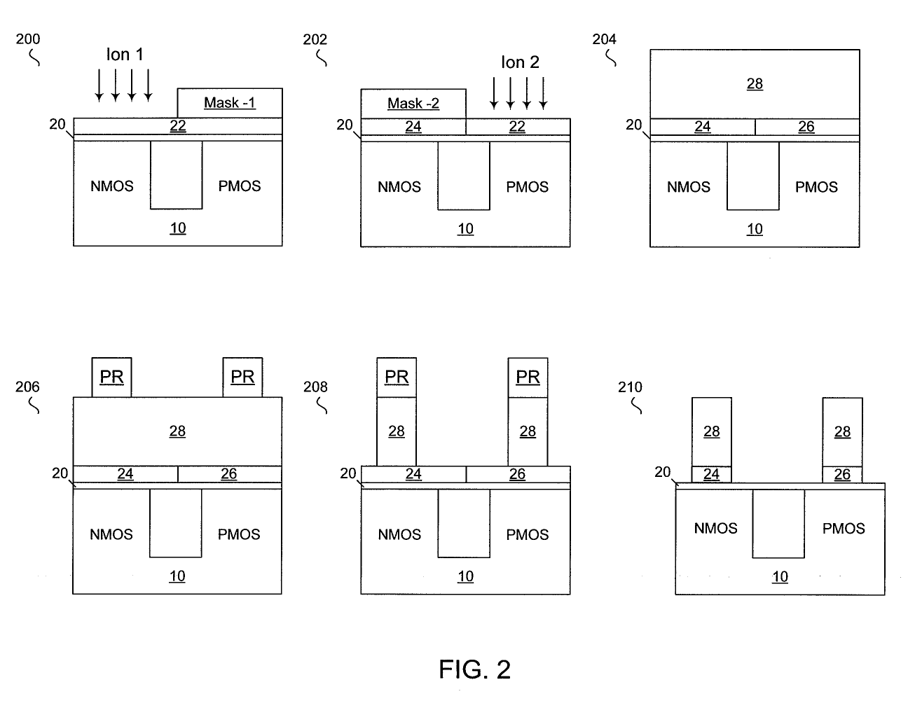

In one embodiment, referring to step 200 of FIG. 2, a high-k gated dielectric layer 20 may be deposited using techniques such as, but not limited to, physical vapor deposition (PVD), chemical vapor deposition (CVD), atomic layer deposition (ALD), or the like. After the high-k gate dielectric layer is deposited, a common metal element used to form a dual metal gate may be deposited. Referring to step 200 of FIG. 2, a matrix film 22 may be deposited using techniques including, without limitation, PVD, CVD, or ALD. The matrix film may include, without limitation, metal layer, a metal alloy layer, or a metal nitride layer. In the non-limiting embodiment of FIG. 2, silicon nitride (SiN) may be deposited to form matrix film 22 and may be used in both the formation of the metal layers (24 and 26 in steps 202 and 204, respectively).

Next, a lithography mask (Mask 1 in FIG. 2) may be deposited and patterned to protect one active area of substrate 10. For example, as shown in step 200 of FIG. 2, the mask is deposited and patterned to protect the PMOS active region of substrate 10 and exposing matrix film 22 over the NMOS active region. The mask may be a hardmask. Alternatively, the mask may be a photoresist layer, an oxide layer, a nitride layer, or any other layers suitable for protecting an area during an ion implantation step.

To form a first metal layer, a first ion implantation step may be performed, as shown in step 200 of FIG. 2. The ion implantation step may include, for example, a plasma doping, an ultralow energy implantation, an energetic molecular and cluster beam implantation, a solid/gas phase doping implantation, a molecular beam deposition, an atomic layer epitaxy or other ion implantation techniques known in the art.

It is noted here that while the embodiment of FIG. 2 shows the NMOS metal layer (24) is formed in step 202 and the PMOS metal layer (26) is formed in step 204, simple modifications may be made such that the PMOS metal layer may be processed prior to the formation of the NMOS metal layer. For example, Mask 1 may be deposited over the NMOS active region and exposing a portion of matrix film 22 over the PMOS region. An ion implantation step depositing a metal such as titanium may to the exposed portion of matrix film 22, forming a PMOS metal layer. Subsequently, Mask 2 may be deposited over the PMOS active region, exposing a portion of matrix film 22 over the NMOS active region. An NMOS metal layer may be formed after the ion implantation of a metal such as tantalum.

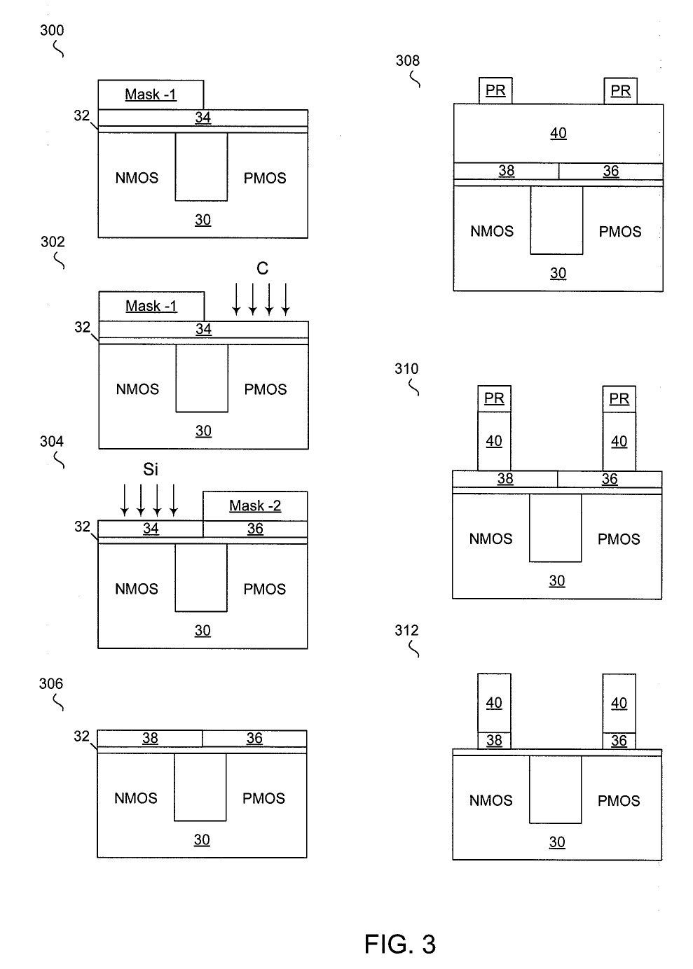

In other embodiments, a common metal, for example, a metal alloy may be deposited using techniques known in the art to form common layer 34 on high-k dielectric layer 32 of substrate 30, as shown in step 300 of FIG. 3. In one embodiment, common layer 34 may include tantalum nitride (TaN) which may be common in the dual metal gates formed in subsequent steps. Next, Mask 1 may be deposited onto common layer 34 and etched such that one active area may be protected and a portion of common layer 34 may be exposed. In one embodiment, the mask layer may protect the NMOS active region of substrate 30 and the exposed portion of common layer 34 may be the area above the PMOS active region.

Next, in step 302, a dopant may be implanted in the exposed portion of common layer 34 via a plasma doping, an ultralow energy implantation, an energetic molecular and cluster beam implantation, a solid/gas phase doping implantation, a molecular beam deposition, an atomic layer epitaxy or other ion implantation techniques known in the art to form first metal layer 36. Alternatively, a plasma carbonization process may be used to incorporate the dopant into common layer. For example, the dopant may include carbon (C) such that a tantalum carbon nitride (TaCN) PMOS metal layer (36) may be formed. Mask 1 may subsequently be removed after PMOS metal layer 36 is formed.

In step 304, a Mask 2 may be deposited onto PMOS metal layer 36 and common layer 34 and etched such that PMOS metal layer 36 may be protected and a portion of common layer 34 may be exposed. In one embodiment, Mask 2 may be deposited and etched such that the PMOS metal layer 36 may be protected, exposing a portion of common layer 34 over the NMOS active region. Next, a dopant may be implanted into the exposed portion of common layer 34, forming a second metal layer (38). For example, the dopant may be silicon such that a tantulum silicon nitride (TaSiN) NMOS metal layer may be formed. Mask 2 may subsequently be removed after second metal layer 38 is formed.

In alternative embodiments, Mask 1 may protect the PMOS active region of substrate 30 and the exposed portion of common layer 34 may be above the NMOS region. A dopant may be implanted to form an NMOS metal layer. Next, Mask 2 may be deposited and etched such that the NMOS metal layer may be protected and exposing a portion of common layer 34 above the PMOS active layer. A dopant may be implanted into the exposed portion of common layer 34 and may form a PMOS metal layer adjacent to the NMOS metal layer.

After first metal layer 36 and second metal layer 38 are formed, a cap may be deposited. For example, the cap may include a crystalline cap layer including, without limitation, silicon or amorphous silicon. In one embodiment, the crystalline cap layer 40 may be deposited over first metal layer 36 and second metal layer 38, as shown in step 308. In some embodiments, crystalline cap layer 40 may include an amorphous silicon cap layer. Next, a photoresist layer (denoted PR in step 310 and 312) may be deposited onto crystalline cap layer 40 and patterned using techniques known in the art to protect the area for the gate stacks.

In step 310, an etching process, selective to first metal layer 36 and second metal layer 38 may be used to etch the a-Si cap. Next, a simultaneous etching process, pertinent to both first metal layer 36 and second metal layer 38 may be performed, as seen in step 312. In one embodiment, a metal or plasma etch process may be used. Alternatively, other techniques known in the art for etching both first metal layer 36 and second metal layer 38 simultaneously may be used.

It is noted that the ions shown in FIG. 3 are non-limiting examples and that other ions may be used. Depending on the material makeup of common layer 34, the ions may be chosen may be based on their workfunctions such that first metal layer 36 and second metal layer 38 are separate, distinct metal layers. Additionally, common metal layer may include, without limitation any metal, metal alloys, or metal nitrides. For example, common layer 34 may be titanium nitride (TiN), tungsten nitride (WN), or tantalum molybdenum nitride. In some embodiments, if a dopant such as silicon is deposited into either titanium nitride (TiN),

In the embodiment where the first metal layer is an NMOS metal layer, the ion implantation may include implanting, for example, tantalum into the exposed matrix layer over the NMOS active layer, forming TaSiN metal layer.

Once the first metal layer is formed (24 in step 202 as shown in FIG. 2), Mask 1 may removed using techniques such as an etching process. After Mask 1 is removed, Mask 2 may be deposited and patterned such that Mask 2 protects an active area opposite from Mask 1. For example, as shown in step 202, Mask 2 may be deposited onto first metal layer 24 and matrix film 22 and patterned such that Mask 2 protects first metal layer 24, exposing matrix film 22 over the PMOS active region. Next, a second ion implantation process may be implemented, where an ion, such as but not limited to titanium (Ti) or aluminum (Al) may be deposited into matrix film 22 for forming second metal layer 26. As shown in the non-limiting embodiment of FIG. 2, the second metal layer is a PMOS metal layer, where a PMOS metal such as, but not limited to titanium (Ti) may be deposited and a TiSiN metal layer is formed.

In step 204, after the second ion implantation of step 202 is completed and second metal layer 26 is formed, Mask 2 may be subsequently be removed using techniques known in the art. Next, a cap such as but not limited to, a crystalline cap layer may be deposited. In one embodiment, amorphous silicon cap 28 may be deposited over the entire device, e.g., over first metal layer 24 and second metal layer 26. Next, in step 206, a photoresist layer (denoted PR in step 206 and 208) may be deposited onto a-Si cap 28and patterned using techniques known in the art to protect the area for the gate stacks.

In step 208, an etching process, selective to first metal layer 24 and second metal layer 26 may be used to etch a-Si cap 28. Next, a simultaneous etching process, pertinent to both first metal layer 24 and second metal layer 26 may be performed, as seen in step 210. In one embodiment, a metal or plasma etch process may be used. If first metal layer 24 and second metal layer 26 are thin enough, a plasma etch process with a large physical bombardment component may be used to achieve comparable etch rates of the two metal layers. By minimizing the differences between the gate stacks in the NMOS and PMOS regions, the difficulty in gate stack patterning may be significantly reduced. After the formation of the dual metal gate stack, the photoresist layer may be removed. tungsten nitride (WN), or tantalum molybdenum nitride, a titanium silicon nitride, tungsten silicon nitride, or tantalum molybdenum silicon nitride metal layer may be formed, respectively.

In some respects, the tuning of a work function of a resultant gate structure may be done by first implanting ions into high-k dielectric layer 20 of FIG. 2 or 32 of FIG. 3 prior to the deposition of a first metal layer or common layer 22 or 34 of FIG. 2 and FIG. 3, respectively. Alternatively, the work function may be tuned by implanting ions after the metal gates are formed (i.e., after steps 200 and 202 in FIG. 2 or steps 302 and 304 of FIG. 3). In some embodiments, ions such as fluorine, silicon, nitrogen, chlorine, oxygen, or other ions may be implanted using techniques known in the art such as plasma doping, ultralow energy implantation, energetic molecular and cluster beam implantation, a solid/gas phase doping implantation, a molecular beam deposition, an atomic layer epitaxy, or the like. The results of the ion implantation into a high-k dielectric layer or a metal gate layer may tune the work function, as shown in FIG. 5, where fluorine implantation was used. The result of the tuning of the work function ultimately affects the threshold voltage.

The above methods for fabricating dual metal gate stacks for CMOS devices reduce or even substantially eliminate the challenges of the conventional process. First, the differences between the NMOS gate stack and the PMOS gate stack are kept to a minimum allowing for a simple, simultaneous etching process. Also, by reducing the number of etching steps, the effect on the gate dielectric layer is minimized, thus reducing the number of defects on a wafer.

In some respects, the above method may be used for fabricating other double gate devices such as, but not limited to, FINFET devices, double gate MOSFETs, other non-planar devices, and the like. For example, U.S. Pat. No. 6,815,268 to Yu et al., incorporated herein by reference, discloses techniques for forming gates in a FINFET device. Without changing the methodologies of fabricating the gate device, e.g., using the conventional layouts and process techniques to fabricate either planar MOSFETs or FINFETs, the methods of the present disclosure may be used to tune the work function of the gates, and more particularly, form the dual gate components of the device.

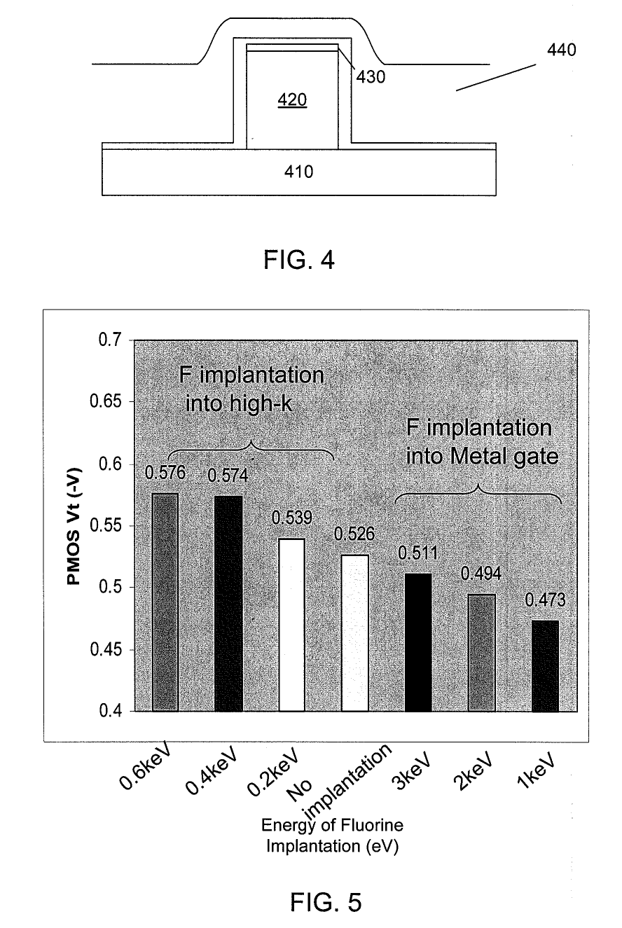

In some embodiments, due to the non-planar aspects of the FINFET devices, an implantation step, such as steps 200 or 202 of FIG. 2 or steps 302 or 304 of FIG. 3 may be performed at an angle. Referring to FIG. 4, a FINFET formed with a high-k gate dielectric is shown. Substrate 410 may include a silicon fin 420, dielectric cap 430 and high-k oxide layer 460, all formed using conventional techniques. The deposition of a metal, such as tantulum, tantulum nitride, tungsten, or other suitable metals may be deposited using, for example, all or some of the steps shown in FIG. 2 or FIG. 3

All of the methods disclosed and claimed can be made and executed without undue experimentation in light of the present disclosure. While the methods of this invention have been described in terms of embodiments, it will be apparent to those of skill in the art that variations may be applied to the methods and in the steps or in the sequence of steps of the method described herein without departing from the concept, spirit and scope of the invention. All such similar substitutes and modifications apparent to those skilled in the art are deemed to be within the spirit, scope, and concept of the disclosure as defined by the appended claims.

1. A method comprising:
providing a substrate having two active regions and a gate dielectric;
depositing a common metal layer over the gate dielectric;
depositing a first mask layer over the common metal layer;
patterning the first mask layer to expose a first portion of the common metal layer;
implanting a first ion into the first portion of the common metal layer to form a first metal layer;
depositing a second mask layer over the common metal layer;
patterning the second mask layer to expose a second portion of the common metal layer; and
implanting a second ion into the second portion of the common metal layer to form a second metal layer.

2. The method of claim 1, the two active regions comprising an NMOS active region and a PMOS active region.

3. The method of claim 1, the common metal layer being selected from the group consisting of a metal layer, a metal alloy layer, and a metal nitride layer.

4. The method of claim 3, the common metal layer comprising a metal nitride layer.

5. The method of claim 4, the metal nitride layer comprising a silicon nitride layer.

6. The method of claim 5, the first ion being selected from the group consisting of tantalum, titanium, and aluminum.

7. The method of claim 5, the second ion being selected from the group consisting of tantalum, titanium, and aluminum.

8. The method of claim 4, the metal nitride layer being selected from the group consisting of tantalum nitride, titanium nitride (TiN), tungsten nitride (WN), and tantalum molybdenum nitride.

9. The method of claim 8, the first ion comprising silicon and the second ion comprising carbon.

10. The method of claim 8, the first ion comprising carbon and the second ion comprising silicon.

11. The method of claim 1, further comprising, after the step of the implanting the first ion, removing the first mask layer.

12. The method of claim 1, further comprising, after the step of the implanting the second ion, removing the second mask layer.

13. The method of claim 1, further comprising, after the step of implanting a second ion, depositing a cap layer.

14. The method of claim 13, the cap layer comprising a crystalline cap layer.

15. The method of claim 14, the crystalline cap layer comprising a silicon cap layer or an amorphous silicon cap layer.

16. The method of claim 13, further comprising, after the step of depositing a cap layer, depositing a photoresist layer onto the cap layer, and patterning the photoresist layer.

17. The method of claim 16, further comprising, after the step of patterning the photoresist layer, etching the cap layer to form a first and second gate stack area, the first gate stack area comprising the first layer and the second gate stack layer comprising the second metal layer.

18. The method of claim 17, after the step of etching the cap layer, simultaneously etching the first and second metal layer of the first gate stack area to form a first gate stack, and etching the second metal layer of the second gate stack area to form a second gate stack.

19. The method of claim 1, further comprising depositing an ion to the gate dielectric prior to depositing the common metal layer.

20. A method comprising:
providing a substrate having a NMOS active region, a PMOS active region, and a gate dielectric;
depositing a silicon nitride layer over the gate dielectric;
depositing a first mask layer over the silicon nitride layer;
patterning the first mask layer to expose a first portion of the silicon nitride layer;
implanting a first ion into the first portion of the silicon nitride layer to form a NMOS metal layer;
depositing a second mask layer over the silicon nitride layer;
patterning the second mask layer to expose second portion of the silicon nitride layer; and
implanting a second ion into the second portion of the silicon nitride layer to form a PMOS metal layer.

21. The method of claim 20, the first ion comprising tantalum.

22. The method of claim 20, the second ion comprising titanium or aluminum.

23. A method comprising:
providing a substrate having a NMOS active region, a PMOS active region, and a gate dielectric;
depositing a nitride layer over the gate dielectric;
depositing a first mask layer over the nitride layer;
patterning the first mask layer to expose a first portion of the nitride layer;
implanting a first ion into the first portion of the nitride layer to form a NMOS metal layer;
depositing a second mask layer over nitride layer;
patterning the second mask layer to expose second portion of the nitride layer; and
implanting a second ion into the second portion of the nitride layer to form a PMOS metal layer.

24. The method of claim 23, the nitride layer being selected from the group comprising silicon nitride, tantalum nitride, titanium nitride (TiN), tungsten nitride (WN), and tantalum molybdenum nitride.

25. The method of claim 23, the first ion comprising silicon and the second ion comprising carbon.
